(19) United States
(12) Patent Application Publication
(10) Pub. No.: US 2011/0317393 A1
(43) Pub. Date: Dec. 29, 2011

(54) Operating Container for a Magnetic Resonance Apparatus

(76) Inventor: Matthias Drobnitzky, Spardorf (DE)

(21) Appl. No.: 13/165,018

(22) Filed: Jun. 21, 2011

(30) Foreign Application Priority Data
Jun. 23, 2010 (DE) 10 2010 024 731.6

(51) Int. Cl. H05K 9/00

(52) U.S. Cl. 361/818

(57) ABSTRACT

An operating container for a magnetic resonance apparatus is proposed. The container has outer walls that enclose an interior space which is embodied for accommodating and operating a magnetic resonance apparatus. The container has a magnetic field shield arranged inside the outer walls. A latent heat storage material is arranged between the outer walls and the magnetic field shield.

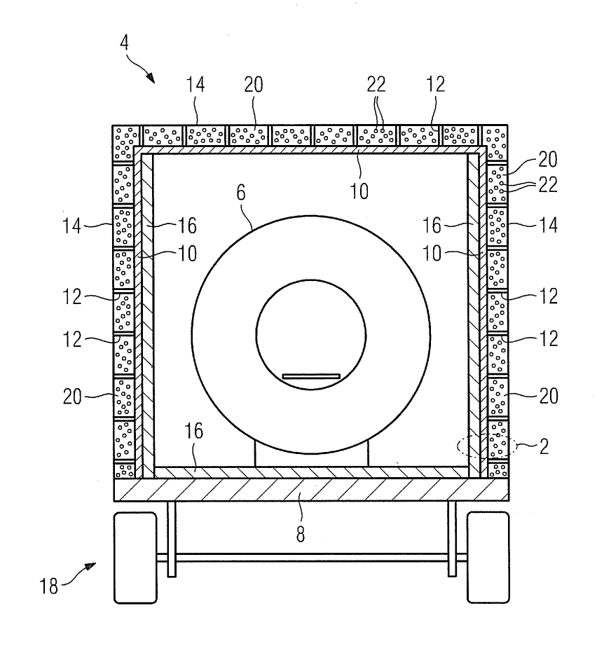

### CROSS REFERENCE TO RELATED APPLICATIONS

This application claims priority of German application No. 10 2010 024 731.6 filed Jun. 23, 2010, which is incorporated by reference herein in its entirety.

### FIELD OF THE INVENTION

The invention relates to an operating container for a magnetic resonance apparatus.

### BACKGROUND OF THE INVENTION

A mobile magnetic resonance apparatus which is permanently installed in the cargo space of a truck trailer is described in U.S. Pat. No. 5,994,903. A magnetic field shielding arrangement is present in addition due to the fact that a magnetic resonance apparatus generates a considerable stray magnetic field. The magnetic field shielding arrangement comprises a shielding coil which is activated during transportation and thereby reduces the stray field on the exterior of the trailer to an acceptable level. In the park position during the operation of the magnetic resonance apparatus the shielding coil can be deactivated because then the safety margin with respect to the magnet, defined by way of the maximally permissible stray magnetic field, can be established by means of access lockouts.

A passive magnetic field shielding arrangement for a mobile magnetic resonance apparatus is described in US2006/0186884A1. The magnetic field shielding arrangement comprises sheets made of a ferromagnetic material which are mounted separated by a gap from the outer walls of the operating container.

For structural reasons the magnetic field shielding panels are closer to the magnet and less insulated from the environment than in the case of stationary magnetic resonance systems. Changing weather conditions can lead to extreme spatial and temporal variations in the amounts of heat input into the magnetic field shield. Changes in length due to the fluctuations in temperature alter the shim status of the magnet in the magnetic resonance apparatus, resulting in changes in the magnetic resonance frequency with consequential limitations in respect of image quality. In the context of quality checks, therefore, a check is also carried out in the case of magnetic resonance apparatus to determine the influence of changing weather conditions on frequency stability.

Manufacturers of containers, in particular of trailers, for mobile magnetic resonance apparatus aim to achieve a mounting of the magnetic field shield that is largely decoupled both mechanically and thermally from the outer walls of the operating container. Since the weight of a magnetic field shield can typically amount to several metric tons, its assembly and installation necessarily entail a high constructional overhead. A special thermal shielding arrangement is generally also required in order to reduce the thermal load. Toward that end thermal insulation is conventionally installed inside the outer walls of the trailer in the form of panels made of synthetic organic foams having as low a coefficient of thermal transmission as possible. With this construction principle the desired thermal insulation is in competition with the space constraints in the interior of the container and with its permissible external dimensions.

### SUMMARY OF THE INVENTION

The object underlying the invention is therefore to disclose a container design for a mobile magnetic resonance apparatus which substantially reduces thermal variations on the magnetic field shield arranged inside the container. The container has outer walls that enclose an interior space which is embodied for accommodating and operating a magnetic resonance apparatus, and has a magnetic field shield arranged inside the outer walls.

The object is achieved according to the invention by means of the arrangement disclosed in independent claim.

Accordingly the invention is realized on an operating container for a magnetic resonance apparatus, said container having outer walls that enclose an interior space which is embodied for accommodating and operating a magnetic resonance apparatus, and having a magnetic field shield arranged inside the outer walls. An operating container shall be understood to mean a container which is equipped in such a way that a magnetic resonance apparatus can be operated in its interior space. Integrally included therein are a correspondingly large interior space and also corresponding connections for the power supply and if necessary for cooling equipment.

According to a first inventive solution approach, the operating container is characterized in that latent heat storage material is arranged between the outer walls and the magnetic field shield.

Latent heat storage materials are characterized by reversible phase transitions (e.g. melting, crystallization, dissolution processes or modification conversion processes) in a target temperature range and within this range can absorb a particularly large amount of heat and also release said heat again. Accordingly, the latent heat storage material according to the invention disposed between the container walls and the magnetic field shield utilizes the heat supplied or dissipated, dependent on weather conditions, for an internal, reversible phase conversion, instead of, as in the case of a traditional means of insulation, passing on the heat, albeit slowly. Materials adapted to the climatic conditions at the planned deployment location of the container have the effect of preventing the undesirable heating-up of the magnetic field shield and avoiding the image quality problems associated therewith. State-of-the-art salt- or paraffin-based latent heat storage materials have physical properties that have been developed for different applications and are available for virtually all temperature ranges.

An advantageous embodiment of the invention is characterized in that the outer walls include a floor section and in that a chassis is mounted under the floor section. Said embodiment as a trailer or semitrailer for a towing vehicle is particularly advantageous for changing deployment locations.

### BRIEF DESCRIPTION OF THE DRAWINGS

An exemplary embodiment of the invention is explained below with reference to the FIGURE.

### DETAILED DESCRIPTION OF THE INVENTION

The FIGURE shows in a schematic cross-sectional view a wall structure 2 of an operating container 4 for a mobile magnetic resonance apparatus 6. Built on a stable floor construction 8 is a supporting frame 10 to which outer walls 14 of the operating container 4 are secured via thermally insulating fixing elements 12. For clarity of illustration reasons not all the fixing elements shown in the FIGURE are labeled with the reference numeral 12. Likewise secured to the supporting frame 10 are panels made of magnetic material which in combination form a magnetic field shield 16. In the present case, in the interests of keeping the overall weight to an absolute minimum, no magnetic field shield 16 is provided on the ceiling of the operating container 4. It can be assumed that above the operating container 4 there will be no space that requires to be shielded against strong magnetic fields.

The entire operating container 4 is connected via the floor construction 8 to a chassis 18. The operating container 4 together with the chassis 18 forms a trailer or semitrailer for a towing vehicle.

Located between the outer walls 14 and the magnetic field shield 16 is an intermediate space 20 that is filled with a latent heat storage material. The filling with the latent heat storage material is indicated in the FIGURE by means of small circles 22. A suitable latent heat storage material is available under the trade name Micronal. Said latent heat storage material (Micronal) is marketed in the form of dispersion and powder with phase change temperatures at 21, 23 and 26 degrees Celsius.

The latent heat storage material introduced into the intermediate space 20 serves as a temperature buffer for compensating weather-related temperature changes. It consists of microscopically small plastic capsules containing a core of wax. The wax has been selected such that it exhibits a phase transition from solid to liquid at the so-called switching temperature. If the temperature of the latent heat storage material rises above its switching temperature (23° C. or 26° C. in the case of Micronal), the wax inside the microcapsules liquefies, absorbing heat in the process. If, on the other hand, the temperature drops below said switching temperature, the wax solidifies and the capsules give off heat. The periodic and abrupt temperature swings lead to a succession of melting and solidifying processes. The latent heat storage material can thus contribute toward absorbing temperature peaks to the extent that it is discharged—e.g. overnight—by cooling down.

1.-3. (canceled)

4. An operating container for a magnetic resonance apparatus, comprising:
outer walls that enclose an interior space for accommodating and operating the magnetic resonance apparatus;
a magnetic field shield arranged inside the outer walls; and
a latent heat storage material arranged between the outer walls and the magnetic field shield.

5. The operating container as claimed in claim 4, wherein the magnetic field shield is a passive shielding arrangement.

6. The operating container as claimed in claim 4, wherein the outer walls comprises a floor section.

7. The operating container as claimed in claim 6, wherein a chassis is mounted under the floor section.
